(19) United States
(12) Patent Application Publication
(10) Pub. No.: US 2012/0241788 A1
(43) Pub. Date: Sep. 27, 2012

(54) Textured Light Emitting Devices and Methods of Making the Same

(75) Inventors: James Carey, Waltham, MA (US); J. Caleb Franklin, Manchester, NH (US)

(73) Assignee: SiOnyx, Inc., Beverly, MA (US)

(21) Appl. No.: 13/286,068

(22) Filed: Oct. 31, 2011

Related U.S. Application Data
(60) Provisional application No. 61/408,551, filed on Oct. 29, 2010.

(51) Int. Cl. H01L 33/22; H01L 33/52

(52) U.S. Cl. 257/98; 438/27; 257/E33.059; 257/E33.074

(57) ABSTRACT

Light emitting devices having a textured light emission surface and methods are disclosed. A light emitting device can include a semiconductor substrate having a light emission surface, a semiconductive junction and a textured region formed via laser irradiation on the light emission surface. During us of the light emitting device, light generated by the semiconductive junction can primarily emit through the light emission surface having the textured region.

### PRIORITY DATA

This application claims the benefit of U.S. Provisional Patent Application Ser. No. 61/408,551, filed on Oct. 29, 2010, which is incorporated herein by reference in its entirety.

### TECHNICAL FIELD

This application relates to light emitting devices having roughen or textured surfaces for enhanced light emitting properties. More specifically, the present disclosure relates to shallow texturing of semiconductor materials by laser irradiation.

### BACKGROUND

Light emitting diodes (LEDs) have gained interest over the past couple decades as a more efficient and alternative solution to incandescent and fluorescent lights. LEDs are comprised of a semiconductor material that can convert electrical energy to light. FIG. 1 shows the cross sectional view of a traditional LED, 100. Traditional LEDs are typically formed of a III-V semiconductor and are doped with at least one p-type region, 102, at least one n-type region 104, and an active region or quantum well region 106 disposed between the doped regions, thereby forming a diode. A p-type contact region 110 and an n-type contact 108 can be coupled to their respective regions such that a bias is applied to the diode to generate light.

The efficiency of traditional LEDs has improved in recent years, to the point of being as efficient as incandescent lights. Internal quantum efficiency via epitaxial growth and light extraction advances have improved the overall efficiency of the LEDs. Most light generated in a typical LED is internally reflected until it is absorbed or traverses an interface at an angle allowing the light to be emitted to the outside. In an attempt to resolve this issue, surface texturing or roughening can aid in extracting light out of the device.

One common roughening or texturing technique used today is chemical etching. The etching process can be a dry or wet chemical etch. A wet etch typically involves placing a semiconductor wafer in an aqueous solution containing an acid or base, such as KOH. By choosing the proper chemicals, the semiconductor material can be removed to create surface features (i.e. texturing) on the surfaces exposed to the aqueous solution. However, these etching techniques have limitations. For example, should the acid (or base) remain in contact with the wafer for more time than is necessary, the acid (or base) could damage the wafer to a degree that would be detrimental to the performance of the LED. As another example, if the etch removes too much material, it can reach the active region and reduce the amount of light that can be generated therein or destroy the LED completely. A graphical representation of a device damaged by too much etching is shown in FIG. 2. In FIG. 2, a roughened surface, 112, is formed on an n-type doped region 104 by way of a chemical roughening process. The figure illustrates portions of the roughened surface that extend into the active or quantum well region 106. In addition, the acid (or base) process can create a non-uniform surface topology resulting in poor device reliability performance. In addition, the cost associated with purchasing and disposing of the acid (or base), as well as the impact of the chemicals on the environment, makes these types of roughening methods less than desirable. Other common texturing techniques include electron beam lithography, nano-imprint lithography, as well as other lithography process known to those skilled in the art.

### SUMMARY

The present disclosure is directed towards the use of a pulsed laser to create a textured and/or roughened surface on at least one surface of an LED device. The device may include a semiconductor substrate, in particular a substrate from the III-V group or a high bandgap semiconductor material. The substrate can also include a semiconductive junction having an n-type region, and a p-type region and operable to emit light. A light emission surface is contemplated on at least one surface the light emitting device. At least a portion of the light emission surface can be textured or roughened via laser irradiation with random surface features configured to increase light extraction.

In another embodiment, a method of manufacturing a light emitting device is provided. Such a method can include the steps of providing a semiconductor substrate having a light emission surface and at least two doped regions, irradiating at least a portion of the light emission surface with laser irradiation to form surface features on the light emission surface, and coupling at least one electrical contact to the light emission surface. The laser irradiation causes the material to be ablated or removed from the substrate or reflowed on the substrate resulting in a textured surface. The method can further include the step of disposing a reflective material on a surface of the semiconductor substrate opposite or adjacent to the light emission surface. It should be noted that the reflective material may serve as an electrical contact (i.e. backside contact) for the light emitting device, depending on the reflective material used.

### BRIEF DESCRIPTION OF THE DRAWINGS

For a fuller understanding of the nature and advantage of the present disclosure, reference is being made to the following detailed description of preferred embodiments and in connection with the accompanying drawings, in which:

FIG. 1 illustrates a cross-sectional view of a prior art light emitting device;

FIG. 2 shows a cross-sectional view of a prior art light emitting device with an etched textured light emission surface;

FIG. 3 shows a cross-sectional view of a light emitting device having textured light emission surface according to one embodiment of the present disclosure;

FIG. 4 illustrates a cross-sectional view of a light emitting device having a textured light emission surface and reflective textured region according to another embodiment of the present disclosure; and

FIG. 5 shows a cross-sectional view of a light emitting device having a textured light emission surface and same side ohmic contacts according to yet another embodiment of the present disclosure.

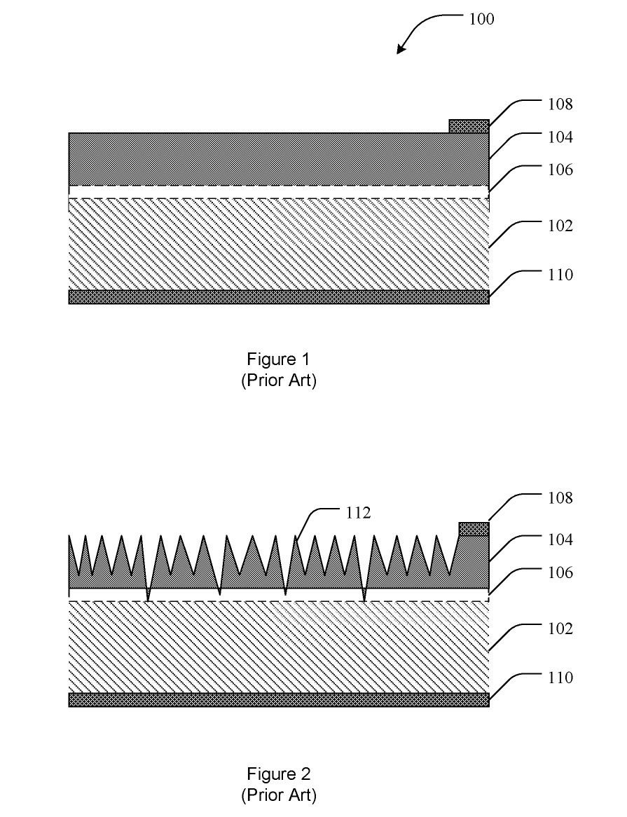

### DETAILED DESCRIPTION

Before the present disclosure is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It should be noted that, as used in this specification and the appended claims, that singular forms “a” and, “the” include plural referents unless the context clearly dictates otherwise. Thus, for example, reference to “a dopant” includes one or more of such dopants, and reference to “the wavelength” includes reference to one or more of such wavelengths.

As used herein, the term “textured surface” refers to a surface having a topology with nano- to micron-sized surface variations or features. The surface features can be arranged in an ordered pattern, a disordered pattern, a random pattern, or the like. Although any texturing technique is considered to be within the present scope, in one aspect the texturing is formed by the irradiation of laser pulses. Furthermore, while the characteristics of a textured surface can be variable depending on the materials and techniques employed, in one aspect such a surface can be several hundred nanometers thick and made up of nanocrystallites (e.g. from about 10 to about 500 nanometers), nanopores, and the like. The surface features can have a size less than about λ/5, where λ is a wavelength of light that is generated by the active region and emerges from the light emitting device via the light emission surface.

As used herein, the terms “surface modifying,” “surface modification,” and “texturing” can be used interchangeably, and refer to the altering of a surface of a semiconductor material using a texturing technique. In one specific aspect, surface modification can include processes using primarily laser radiation, whereby the laser radiation facilitates the removing of material or ablating a surface of the semiconductor material. Accordingly, in one aspect surface modification includes doping the material.

As used herein, the term “fluence” refers to the amount of energy from a single pulse of laser radiation that passes through a unit area. In other words, “fluence” can be described as the energy density of one laser pulse.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

As used herein, the term “absorptance” refers to the fraction of incident electromagnetic radiation absorbed by a material or device.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

The present disclosure provides a light emitting device including a semiconductor substrate having a light emission surface, a semiconductive junction formed from a p-type region and an n-type region, and a textured region formed via laser irradiation on the light emission surface. The textured region or surface is operable to increase light emission generated from the active region primarily through the light emission surface. In one embodiment, the semiconductor substrate can be comprised of III-V or II-VI type semiconductor material. In one embodiment, a semiconductor substrate can have surface features positioned and/or arranged to facilitate the extraction of at least a portion of the light generated within the device.

The present disclosure offers advantages over traditional roughened LED devices and methods. For example, methods disclosed herein offer the ability to control the size of the surface features; control of the amount of material that is removed from the surface, i.e. shallow texturing is good for thin layers; less expensive texturing process and the ability to include dopants when lasing for enhance performance.

Light is generated in a light emitting device such as a light emitting diode (LED) by applying an electrical current to the LED and holding the p-type region contact at a positive potential relative to the n-type region contact. This positive potential allows current to flow into the device such that electrons can recombine with electron holes thereby releasing energy in the form of photons. This effect is known as electroluminescence and the emitted color is dictated by the energy gap of the semiconductor material.

As previously mentioned, light emitting diodes have suffered light extraction limitations due to the large optical refractive index of the typical semiconductor substrates (GaN, InGaN, AlGaAs, GaAsP, AlGalnP, AlGaP, etc.) The light emitting diodes exhibit large indexes of refraction (about 2.2-about 3.8) relative to air (about 1.0). This index of refraction directly impacts and prevents light from escaping the semiconductor device unless the light is within an escape cone. LEDs generally emit light that is perpendicular or within a few degrees from normal to the LED's semiconductor surface in an optical cone shape, known by those skilled in the art as the escape cone. Photons that fall outside of the escape cone or the maximum angle of incidence cannot escape the device and are reflected until they become absorbed, thereby generating heat. Thus, light extraction has been studied over recent years. In particular, U.S. Pat. Nos. 5,779,924 and 5,955,749 have described LEDs having an ordered textured surface formed via a chemical etch into the top surface of the LED, each reference is incorporated herein in their entirety.

A photonic lattice and/or photonic crystal refers to a surface that can have various ordered, disordered, or random patterns of holes. The ordered patterns can be periodic, non-periodic, quasi-crystal, as well as other ordered patterns. The specific pattern can affect the light emission profile for a given wavelength of light. For example, a green LED having a hexagonal periodic pattern of holes or cones can extract light and/or emit light from a light emission surface in a collimated pattern. These types of patterns can be formed with the laser process described herein. However, random and/or disordered patterns can also be produced with the laser process of the present disclosure.

LEDs having a photonic lattice can be fabricated by various processing steps, including deposition, lift-off, lithography and etching steps. The LED device is fabricated using standard processing steps. The photonic lattice however, can be formed in the top layer of the semiconductor material? through costly and time consuming nanoimprint lithography and etching processes. The present disclosure provides a more simplified process for forming roughened/textured surface (similar to the photonic lattice) using a pulsed laser to ablate the material thereby creating the roughened surface.

The present disclosure contemplates a semiconductor substrate capable of emitting light having a textured or roughen light emission surface. The textured surface can include surface features formed via laser irradiation. The surface features can be configured in an ordered or random pattern. Typically, the features are formed in a random pattern that emits light in a lambertian distribution. Thus, a lens or an optic such as a layer of encapsulant may be used to focus emitted light.

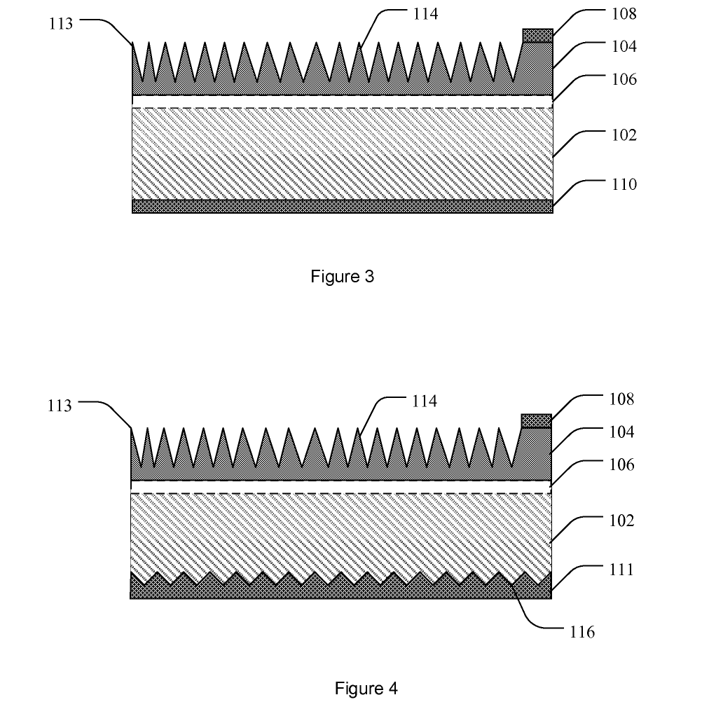

FIG. 3 illustrates a light emitting device according to one aspect of the present disclosure. The light emitting device includes a semiconductor substrate having a plurality of doped regions, 102 and 104. Doped region 102 and 104 can be either n-doped or p-doped, while region 106 is an active quantum well region, which, together with the doped regions, are configured to create a semiconductor junction. In this embodiment, 102 can be the p-doped region and the n-doped region 104, although the alternative configuration is contemplated. Contact regions 108 and 110 can be formed on their respective doped regions, i.e. n-contact formed on n-type region and p-contact formed on p-type region. Surface features 114 are formed on a light emission surface, 113, via a pulsed laser process. These surface features are configured to enhance light emission from semiconductor substrate. Further, a textured reflective region, 111, can be formed on or near a surface opposite of the light emission surface via a pulsed laser process, as shown in FIG. 4. In other words, a textured region is disposed between the semiconductor material and a reflective region, thereby causing the reflective region to have at least one interface that is non-planar and undulated to increase the dispersion of electromagnetic radiation. According, a pulsed laser can form surface features 116 on the backside of semiconductor layer 102 and a reflective material can be disposed on the textured surface 116 thereby creating a reflective textured region that is capable of reflecting light from the back surface to the light emission surface, thus increasing the light emission output of the device. The purpose of the surface features is to diffuse and/or redirect light to increase the chances of the reflective light escaping the semiconductor material. The multiple textured regions or layers in FIG. 4 can have a synergistic effect on enhancing the light emission of the light emitting device. In these figures it should be mentioned that the p-contact layer can include any material that allows electrical current flow. Non-limiting examples include silver, aluminum, and the like, including combinations thereof. For example, a p-contact layer comprised of silver or aluminum can act as a reflective layer as well as an electrical contact. If a reflective layer is employed in the present invention, the reflective layer can be positioned to substantially reflect light through the light emission surface. Non-limiting examples of reflective materials can include aluminum, silver, tungsten, gold, associated alloys and combinations thereof. Bragg reflectors can also be utilized to reflect light through the light emission surface. It should be known to those skilled in the art that same side contacts, i.e. both p-contact and n-contact formed on the same side of the device, can also be realized in any embodiments of the present disclosure.

It is further contemplated that a layer of dielectric material or an encapsulant can be disposed on the light emission surface of the semiconductor layer(s). The dielectric material or encapsulant can be used to focus the light emitting from the device more effectively. In one embodiment, semiconductor material (i.e. layers 102, 104 and 106) is devoid of a surface having surface features operable to further facilitate light extraction. A dielectric layer (or multiple layer stack), such as an oxide (SiO₂) or nitride can be disposed on a light emission surface and can be textured for increasing light extraction there through. In one embodiment, the material can have an index of refraction that is less than the index of refraction of the semiconductor material used. The textured surface can be formed via laser irradiation and the layer can have a thickness in the range of about 1 nm to about 500 nm (I'd make this thicker in some embodiments maybe up to 2 um?). In another aspect, both a dielectric layer and a semiconductive material having a light emission surface can both have a textured surface to enhance light extraction.

The laser processing can be accomplished by any laser process capable of forming a textured layer having the properties according to aspects of the present disclosure. For example, in one aspect the laser processing step can be accomplished with a plurality of laser pulses having a wavelength in the range of about 200 nm to about 1200 nm and a pulse width in the range of about 5 femtoseconds to about 500 nanoseconds. In one embodiment the pulse width is in a range of about 5 femtosecond to about 900 picoseconds. In another embodiment the pulse width is in a range of about 5 picoseconds to about 900 picoseconds. It is also contemplated to use a continuous laser to create the surface features on at least one surface of the semiconductor substrate. The number of laser pulses irradiating the semiconductor substrate can be in the range of about 2 to about 1000. The wavelength selected should be at a frequency that can be absorbed (either linearly or non-linearly) by the top layer such that ablation or removal of semiconductor material is realized. The wavelength of the laser can vary from differing semiconductor substrates. More details to using a pulsed laser can be found in U.S. Pat. No. 7,354,792, which is incorporated by reference in its entirety. In the '792 reference, the laser processing is performed on silicon substrates to enable the substrate to absorb and detect light in the infrared regions. Conversely, the present disclosure seeks not to improve absorption for a specific wavelength of light but the opposite (e.g. to enhance light emission from a semiconductor device).

The resultant surface features in the textured region can be of any height or physical configuration that is formed by laser treatment and can enhance light emission from a light emitting device. In one embodiment, for example, such surface features can have a height (measuring from valley to peak) in the range of about 1 nm to about 4 μm. In another embodiment the surface features can have a height in the range of about 10 nm to about 2 μm. Typically, the features can have a size less than about λ/5, where λ is a wavelength of light that is generated by the active region and emerges from the light emitting device via the light emission surface. The nearest neighboring peak or hole distance can typically be in the range of about 1 nm to about 1 μm. It should be understood, that while the surface features involve shapes such as hemispheres, cones, pillars and pyramids, the surface features can also include holes arranged to increase light emission from the device.

The semiconductor substrate can be any semiconductor material capable of being utilized in a light emitting device. In one embodiment, for example, the semiconductor substrate can be III-V type, II-VI type and other materials. Non-limiting examples of substrate materials can include gallium nitride (GAN), gallium arsenide (GaAs), Indium Gallium Arsenide (InGaAs), Zinc Oxide (ZnO), as well as other common light emitting materials. The thickness of the substrate material can be less than about 400 μm, 200 μm, 100 μm, 10 μm and even 5 μm. Moreover, any one of the semiconductor layers (i.e. p-type, n-type, active region layer) can be less than 20 μm, 10 μm, 2 μm, 1 μm and 500 nm.

Some of the common LED semiconductor materials are typically epitaxially grown on a sapphire substrate. The sapphire substrate is similar to the crystallinity and coefficient of thermal expansion as that of GAN materials and thus is considered a good growth substrate. In addition, sapphire substrates are substantially transparent to visible light. The GAN material can be deposited (i.e. grown) and doped such that either the p-type or n-type region is near the sapphire wafer. The sapphire wafer can later be removed by chemical/mechanical grinding, followed by a chemical mechanical polish (CMP) process step. Alternatively, the sapphire growth substrate can be separated from the GAN material by rapidly heating the interface with a 248 nm laser, as described in U.S. Pat. Nos. 6,071,795 and 6,559,075, which are incorporated by reference in their entireties. The resultant interface of the LED can have a submicron (i.e. less than 100 nm) rough or damaged surface. Normally, LED manufactures may polish this interface to remove any damage. With the current invention, a femtosecond (or picosecond) laser can be used on the newly separated surface/interface to create a random roughen textured surface that will ultimately increasing light extraction from the device. The lasing process can also be used to remove any damage left from the substrate separation step. The femtosecond laser can be tuned to a proper frequency (i.e. wavelength) for a specific semiconductor material that will allow for proper ablating conditions. The resultant surface features will create more surface area thereby increasing the potential of the photons to exit the semiconductor material and not be internally reflected. The amount of material removed can be less than about 2 μm. Further the surface features can have a height of less than about 2 μm. FIG. 4 illustrates a laser textured LED device according to the present disclosure.

It is also contemplated that a growth substrate can be textured prior to a deposition or growth process with surface features that would enable a resultant semiconductor material having a textured surface to be formed thereon. For example, a growth substrate can be comprised of a sapphire material having a textured surface prepared for semiconductor growth. As a semiconductor material is grown thereon, the shapes of the textured sapphire surface can be transferred to the semiconductor material as it is deposited or grown on the sapphire material. The resultant device would thus be devoid of any laser processing damage or side effects.

In another embodiment it is contemplated that the sapphire material can be surface roughened (using a laser) prior to the growth process. The roughened surface can then have a semiconductor material such as GAN to be epitaxially deposited thereon. The surface features would transfer to the growth of the material and eventually, the top surface of the grown GAN material will have a roughened surface. The new surface may not have the same topology as the growth surface, but it will have enough surface modulation to enhance photon extraction from the GAN material.

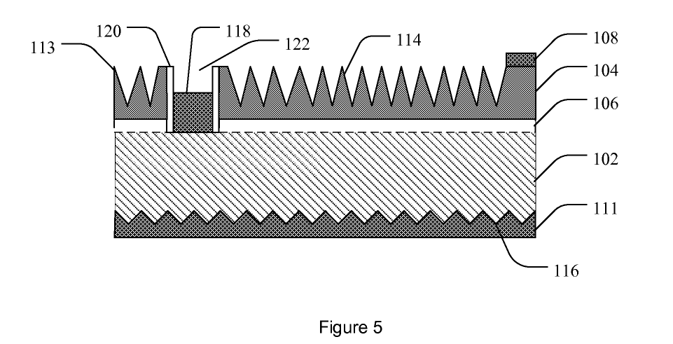

FIG. 5 illustrates a semiconductor material having a p-type region 102, an active (quantum well) region 106 disposed between the p-type region and an n-type region 104. An re-contact 108 can be disposed on a top surface of the n-type layer. The n-type region can be less than 100 μm in thickness. In this embodiment, the n-type region has a top surface that is a light emission surface. The light emission surface can be laser processed to create surface features 114 thereon. A reflective layer can be disposed near a surface of the p-type layer 110 and can have an undulating interface 116. The undulating interface can be formed via pulsed laser irradiation. A p-contact layer 118 can be formed on the same-side as the n-type contact. In this embodiment, an aperture 122 is formed in the n-type layer and active region. A dielectric material 120 is disposed on the side walls of the aperture to passivate the walls. This enables a p-contact material to be coupled to the p-type layer on the same side as the n-contact.

A method of manufacturing a light emitting device capable of enhancing light emission is provided. Such a method can include providing a semiconductor substrate having a light emission surface and at least two doped regions, irradiating at least a portion of the light emission surface of the semiconductor substrate with laser irradiation to form a textured surface on the light emission surface, and coupling at least one electrical contact to the light emission surface. The semiconductor substrate can include materials that are designed to emit light, such as for example, GAN based materials. The laser used in the irradiation step can be a Ti:Sapphire laser capable of emitting laser light having a wavelength in the range of about 200 nm to about 900 nm. In another embodiment the laser can have a wavelength in the range of about 200 nm to about 1550 nm. Other laser devices are also considered to be within the present scope. The irradiation can be pulsed and have a pulse duration of about 5 femtoseconds to about 900 picoseconds. In another embodiment the pulse duration can be about 5 picoseconds to about 900 picoseconds. The energy used for ablation can be describe as fluence and be in the range of about 0.20 J/cm² to about 1 J/cm². After the irradiation step, the semiconductor substrate can be annealed to remove any imperfections induced by the by the laser. The lasing steps can offer surface feature uniformity, the ability to etch/ablate features on a device where desired and is less sensitive to surface conditions before texturing. For example, the laser can laze a desired target region (i.e. a portion of the semiconductor material) thereby facilitating the ability to create a patterned textured thereon.

Furthermore, the method can further include coupling a reflective layer to the semiconductor substrate to reflect light through the emission surface. Typically, the reflective layer is deposited on a surface opposite the light emission surface. Additionally, the method can further include the step of depositing an encapsulant on the device, to passivate, focus the light, or enhance light extraction. The step of irradiating the encapsulant or dielectric layer to form surface features thereon can also be included.

The present invention also contemplates a machine or system capable of laser texturing a semiconductor substrate having a diameter of about 50 mm to about 150 mm (i.e. 2 inch to about 6 inch wafers) in a single machine. In addition the system can process at least about 20 to about 80 wafers per hour. In another embodiment the system can process about 60 wafers per hour. The machine can be automated or manually operated. The system can include a six-axis motion controller for moving a semiconductor wafer in any motion for optimized laser performance.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

1. A light emitting device comprising:
a semiconductor substrate having a light emission surface;
a semiconductive junction having a p-type region and an n-type region, wherein the semiconductive junction is operable to emit light primarily through the light emission surface; and
a textured region formed via laser irradiation on the light emission surface, wherein the textured region is operable to diffuse light emitted through the light emission surface.

2. The light emitting device of claim 1, wherein the laser textured region has surface features having a height in the range of about 1 nm to about 4 microns.

3. The light emitting device of claim 2, wherein the surface features have a height in the range of about 10 nm to about 2 microns.

4. The light emitting device of claim 1, further comprising at least one electrical contact disposed on the p-type region.

5. The light emitting device of claim 1, further comprising at least one electrical contact disposed on the n-type region.

6. The light emitting device of claim 1, further comprising a reflective layer positioned to reflect light through the light emission surface.

7. The light emitting device of claim 6, wherein the reflective layer comprises a metallic material.

8. The light emitting device of claim 7, wherein the metallic material is selected from a group consisting of aluminum, silver, tungsten, gold, alloys and combinations thereof.

9. The light emitting device of claim 1, further comprising an encapsulant disposed on the light emission surface.

10. The light emitting device of claim 1, wherein the encapsulant has a refractive index of less than about 1.5.

11. The light emitting device of claim 1, further comprising a textured surface formed via laser irradiation on the substrate surface opposite the light emission surface.

12. The light emitting device of claim 11, wherein the textured surface comprises surface features.

13. The light emitting device of claim 12, wherein the surface features have a size in the range of about 10 nm to about 2 microns.

14. The light emitting device of claim 1, further comprising a growth substrate.

15. The light emitting device of claim 14, wherein the growth substrate is comprised of sapphire.

16. The light emitting device of claim 14, further comprising surface features disposed on a surface between the growth substrate and the semiconductor substrate.

17. The light emitting device of claim 16, wherein the surface features have a height in the range of about 1 nm to about 4 microns.

18. A method of manufacturing a light emitting device comprising:
providing a semiconductor substrate having a light emission surface and at least two doped regions;
irradiating at least a portion of the light emission surface of the semiconductor substrate with laser irradiation to form a textured surface on the light emission surface;
coupling at least one electrical contact to the light emission surface.

19. The method of manufacturing of claim 18, further comprising the step of positioning a reflective layer about the semiconductor substrate to reflect light through the light emission surface.

20. The method of manufacturing of claim 18, further comprising the step of disposing an encapsulant on the light emission surface.

21. The method of manufacturing of claim 18, wherein the laser irradiation has a wavelength in the range of about 200 nm to about 900 nm.

22. The method of manufacturing of claim 18, wherein the laser irradiation is pulsed laser irradiation.

23. The method of manufacturing of claim 22, wherein the pulsed laser irradiation has a pulse duration of about 5 femtoseconds to about 900 picoseconds.

24. The method of manufacturing of claim 18, wherein the laser irradiation has a fluence in the range of about 0.20 J/cm² to about 1 J/cm².

25. The method for manufacturing of claim 18, further comprising annealing the semiconductor substrate after the irradiation step.
